(19) United States
(12) Patent Application Publication
(10) Pub. No.: US 2005/0180583 A1
(43) Pub. Date: Aug. 18, 2005

(54) Advanced mute function

(76) Inventor: Paul William Bayon, Redding, CA (US)

Correspondence Address: Paul W. Bayon, 20780 Old 44 Drive, Redding, CA, 96003, US

(21) Appl. No.: 10/781,414

(22) Filed: Feb. 17, 2004

(51) Int. Cl. H04B 15/00; H03F 1/14

(52) U.S. Cl. 381/94.5; 330/51

(57) ABSTRACT

A mute button that has a timer function so that the sound will automatically turn back on.

### CROSS REFERENCE TO RELATED APPLICATION

Not Applicable

### FEDERALLY SPONSORED RESEARCH

Not Applicable

### SEQUENCE LISTING OR PROGRAN

Not Applicable

### BACKGROUND OF THE INVENTION—FIELD OF INVENTION

This invention relates to the functionality of a mute button

### BACKGROUND OF THE INVENTION

Currently a person can only turn a mute button on or off

### BACKGROUND OF THE INVENTION—OBJECTS AND ADVANTAGES

This invention relates to improving the functionality of the mute button used with electronic equipment such as radios, television sets etc. Presently the user wants to turn the sound off for a variety of reason but can only turn the sound on or off. If the person wishes to have a device in mute mode for a set period of time, such as when commercials are on and thus wishes to mute the device to avoid listening to the commercials, the user must maintain a vigilance to wait for the period of time to end. This new system would enable to user to put the system into mute mode for a specific period of time and thus avoid further observation to turn the sound back on.

### SUMMARY

A mute button that has a timer function so that the sound will automatically turn back on

### DETAILED DESCRIPTION

If the user estimates or knows that the commercials will be on for the next three minutes and the system is set to mute in 30 second increments then the user can push on the mute button six times, within the shorter period (let say this is set to 5 seconds) of time. This will cause the mute function on the device to be in mute mode for three minutes of time and then turn back on the sound at the end of the three minutes. If during the period of time when the mute has been turned on (and after when the short period of time is up) the user can override the mute to turn the sound back on. This is done by pushing on the mute button once (after the short period of time is up) and the sound will be turned back on.

1) A method by which pushing down one or more times within a short period of time on a mute button for a device results in the mute function of the device staying mute for a period of time.

2) A system using claim 1 that provides an interface to control, set and or change the length of time for which the mute bottom is to stay in mute mode for each time the mute button is pushed in a shorter period of time

3) A system using claim 1 that provides an interface to control, set and or change the length of time the device will use to differentiate between adding more periods of mute (short period of time) or the user desiring to override and turn the sound back on.
